(19) United States
(12) Patent Application Publication
(10) Pub. No.: US 2010/0307801 A1
(43) Pub. Date: Dec. 9, 2010

(54) Multilayer ceramic substrate and manufacturing method thereof

(75) Inventors: Yong Suk Kim, Yongin-si (KR); Yong Soo Oh, Seongnam-si (KR); Byeung Gyu Chang, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/458,958

(22) Filed: Jul. 28, 2009

(30) Foreign Application Priority Data
Jun. 3, 2009 (KR) 10-2009-0049071

(51) Int. Cl. H05K 1/09; H01B 13/00; B05D 5/12; H05K 1/11; H05K 1/02

(52) U.S. Cl. 174/257; 216/13; 427/126.2; 427/555; 427/553; 174/266; 174/259

(57) ABSTRACT

The present invention relates to a multilayer ceramic substrate including: a ceramic stacked structure in which multiple ceramic layers are stacked and interconnected to one another through vias provided in respective ceramic layers, the ceramic stacked structure having surface reforming layers 111a formed by removal of glass component on the surfaces of upper and lower parts of the ceramic layers; and contact pads formed on a top surface and a bottom surface of the ceramic stacked structure so as to be electrically connected to the vias.

### CROSS-REFERENCE TO RELATED APPLICATIONS

This application claims the benefit of Korean Patent Application No. 10-2009-0049071 filed with the Korea Intellectual Property Office on Jun. 3, 2009, the disclosure of which are incorporated herein by references.

### BACKGROUND OF THE INVENTION

1. Field of the Invention

The present invention relates to a multilayer ceramic substrate and a manufacturing method thereof; and, more particularly, to a multilayer ceramic substrate, which has a ceramic stacked structure provided with surface reforming layers, formed by removal of glass component, on surfaces of upper and lower parts of the ceramic stacked structure, and a manufacturing method thereof.

2. Description of the Related Art

The recent trend toward technical development of electric apparatus and thinness of the apparatus itself causes essential integration of its components.

There has been developed a multilayer ceramic substrate formed by stacking a number of ceramic sheets for integration of its components. As the multilayer ceramic substrate has thermal resistance, abrasion resistance, and superior electric characteristics, it has been widely used as a substitute for the conventional print circuit board. Further, the demand for the multilayer ceramic substrate has been increased.

The multilayer ceramic substrate has been used to constitute various electric components, such as a PA module board, an RF diode switch, a filter, a chip antenna, various package components, a complex device, and so on.

Particularly, the multilayer ceramic substrate may be used in a probe substrate of a probe card used for electrical examination of a semiconductor device. Herein, the probe substrate may be composed of multilayer ceramic substrate having contact pads provided on an upper part and a lower part thereof. In this case, the contact pads disposed on the lower part of the multilayer ceramic substrate are in electrical contact with a print circuit board which transmits and receives examination signals from/to an outside. Further, the contact pads disposed on the upper part of the multilayer ceramic substrate may be in contact with probe pins which are electrically connected to a semiconductor device of being an examination target.

In order to manufacture the multilayer ceramic substrate, a ceramic stacked structure is first formed by stacking green sheets in multiple layers and undergoing a firing process. Then, contact pads are formed on each of the top surface and the bottom surface of the ceramic stacked structure so as to be electrically interconnected to an outside.

Herein, the contact pads have a uniform pattern which is obtained by undergoing an etching process and a plating process using resist patterns, which are formed by forming a seed plating layer on the ceramic stacked structure, and performing a Photo Resist (PR) process on the resultant seed layer.

As for the multilayer ceramic substrate having such contact pads formed on the top surface thereof, an HTCC (High Temperature Co-fired Ceramic) substrate or an LTCC (Low Temperature Co-fired Ceramic) substrate is widely used. Herein, the HTCC substrate is heat-treated at a temperature of 1500° C. or higher to thereby form a multilayer substrate. As for material of the HTCC substrate, alumina of 94% or more is used as main material, and a small amount of SiO2 is used as additive. As for material of the contact pad, tungsten W capable of high-temperature firing is mostly used.

Such an HTCC substrate is superior in terms of mechanical strength and chemical resistance characteristics. However, an electrode pattern made of high-temperature fired tungsten W has electrical conductance lower than that of Ag, or Cu, and thus it has inferior high frequency characteristics and has coefficient of thermal expansion higher than two times that of a silicon semiconductor device, which causes an obstacle to the application field requiring matching of coefficient of thermal expansion.

In contrast, an LTCC substrate is heat-treated at a temperature of 900° C. or lower to thereby form a multilayer substrate. The LTCC substrate contains a large amount of glass component having a low melting point so as to be used at a low temperature of 900° C. or lower. As a firing temperature becomes below 900° C., co-firing is possible at a low temperature even in material of a contact pad, which results in use of Ag, or Cu having superior electrical characteristics. Further, resistors, inductors, and capacitors of being passive elements are incorporated into a substrate, and thus the substrate is widely used for convergence, modularization, and high frequency, downsizing of electronic components.

However, since the LTCC substrate contains a large amount of glass component weak to chemical resistance, such as SiO2, CaCO3, and ZnO, the glass component is corroded by chemical solution of strong acids or strong bases, which are used in a PR process, a plating process, and an etching process as described above. Therefore, there are problems such as lowering of adhesive force between the ceramic substrate and the contact pads, difficulty in implementing the contact pads, and degradation of substrate strength.

### SUMMARY OF THE INVENTION

The present invention has been proposed in order to overcome the above-described problems and it is, therefore, an object of the present invention to provide a multilayer ceramic substrate and a manufacturing method thereof, in which surface reforming layers, obtained by removing glass component of the surfaces of the ceramic stacked structure, are formed, and then contact pads are formed on the formed surface reforming layers, thereby preventing corrosion of surfaces of the ceramic stacked structure by chemical solution of strong acids or strong bases used in a PR process, a plating process, and an etching process performed for formation of the contact pads, which results in enhancement of adhesive force between the ceramic stacked structure and the contact pads.

In accordance with one aspect of the present invention to achieve the object, there is provided a multilayer ceramic substrate including: a ceramic stacked structure in which multiple ceramic layers are stacked and interconnected to one another through vias provided in respective ceramic layers, the ceramic stacked structure having surface reforming layers 111a formed by removal of glass component on the surfaces of upper and lower parts of the ceramic layers; and contact pads formed on a top surface and a bottom surface of the ceramic stacked structure so as to be electrically connected to the vias.

Herein, each ceramic layer except for the surface reforming layers of the ceramic stacked structure contains glass component.

Also, the multilayer ceramic substrate further includes conductive adhesive patterns interposed between the contact pads and the ceramic stacked structure.

Also, the conductive adhesive patterns include at least one of Ni, Ti, and Cr.

Also, the multilayer ceramic substrate further includes plating seed patterns interposed between the conductive adhesive patterns and the contact pads.

Also, the contact pads include at least one of Cu, Ni, and Au.

In accordance with still another aspect of the present invention to achieve the object, there is provided a method for manufacturing a multilayer ceramic substrate including the steps of: providing a ceramic stacked structure in which multiple ceramic layers containing glass component are stacked, and are interconnected through vias provided in respective ceramic layers; removing glass component of ceramic layers positioned on surfaces of upper and lower parts of the ceramic stacked structure to thereby form surface reforming layers; and forming contact pads on a top surface and a bottom surface of the ceramic stacked structure having the surface reforming layers formed thereon, the contact pads being electrically connected to the vias.

Herein, in the step of removing glass component of ceramic layers positioned on surfaces of upper and lower parts of the ceramic stacked structure to thereby form surface reforming layers, the glass component is removed from the ceramic layers positioned on the surfaces of the upper and lower parts of the ceramic stacked structure through a chemical treatment method.

Also, the chemical treatment method is based on the fact that the glass component is removed by using chemical solution including at least any one of HF, and HCl as strong acids, and KOH, and NaOH as strong bases.

Herein, in the step of removing glass component of ceramic layers positioned on surfaces of upper and lower parts of the ceramic stacked structure, thereby forming surface reforming layers, the glass component is removed from the ceramic layers positioned on the surfaces of the upper and lower parts of the ceramic stacked structure through a physical treatment method.

Also, the physical treatment method is based on the fact that the glass component is removed by using at least any one of laser beams, a plasma source, and microwave.

Also, the method further includes a step of performing a polishing treatment for surfaces of the surface reforming layers, after step of removing glass component of ceramic layers positioned on surfaces of upper and lower parts of the ceramic stacked structure.

Also, the step of forming contact pads includes the steps of: sequentially forming conductive adhesive layers and plating seed layers on the ceramic stacked structure having the surface reforming layers formed thereon; forming resist patterns on the plating seed layer; performing a plating process on the plating seed layers exposed by the resist patterns, thereby forming the contact pads; removing the resist patterns; and etching parts of the conductive adhesive layers and the plating seed layers exposed by removal of the resist patterns, thereby forming plating seed patterns and conductive adhesive patterns, respectively.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view illustrating a multilayer ceramic substrate in accordance with a first embodiment of the present invention; and

FIGS. 2 to 8 are cross-sectional views sequentially illustrating processes of a method for manufacturing a multiple ceramic substrate in accordance with the embodiment of the present invention.

### DETAILED DESCRIPTION OF THE PREFERABLE EMBODIMENTS

Hereinafter, embodiments of the present invention will be described in detail with reference to the accompanying drawings illustrating a multilayer ceramic substrate. The following embodiments are provided as examples to allow those skilled in the art to sufficiently appreciate the spirit of the present invention. Therefore, the present invention can be implemented in other types without limiting to the following embodiments. And, for convenience, the size and the thickness of an apparatus can be overdrawn in the drawings. The same components are represented by the same reference numerals hereinafter.

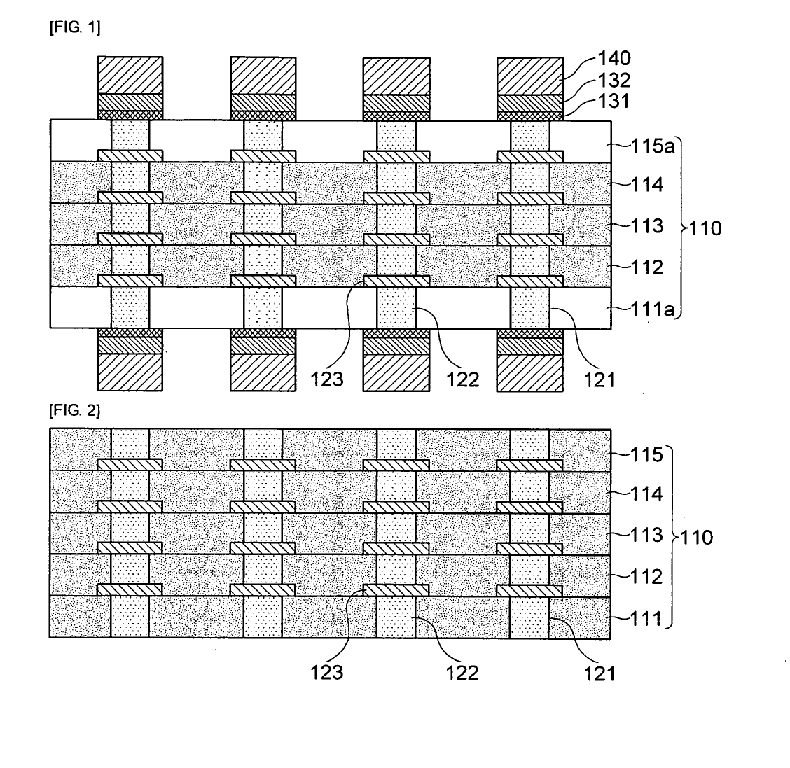

FIG. 1 is a cross-sectional view illustrating a multilayer ceramic substrate in accordance with an embodiment of the present invention.

As shown in FIG. 1, the multilayer ceramic substrate may include a ceramic stacked structure 110, and contact pads 140.

The ceramic stacked structure 110 may include ceramic layers 111a, 112, 113, 114, and 115a formed by being stacked in multiple layers. In this case, the ceramic layers 111a, 112, 113, 114, and 115a formed by being staked in multiple layers are provided with the vias 122 to allow the layers to be interconnected to one another, wherein the vias include a conductive material filled in via holes 121 which pass through their bodies, for example, an Ag paste. Also, inner circuit patterns 123 electrically connected to the vias 122 are further provided in the ceramic stacked structure 110.

In particular, among ceramic layers 111a, 112, 113, 114, and 115a constituting the ceramic stacked structure 110 of the multilayer ceramic substrate in accordance with an embodiment of the present invention, respective ceramic layers 112, 113, and 114 except for ceramic layers positioned on surfaces of upper and lower parts of the ceramic stacked structure 110 may be an LTCC layer that contains a large amount of glass component, such as SiO2, CaCO3, ZnO, B2O3, and so on. The remaining ceramic layers positioned on the surfaces of the upper and lower parts of the ceramic stacked structure may be surface reforming layers 111a, and 115a formed by removing the glass component.

The glass component, such as SiO2, CaCO3, ZnO, and B2O3 is vulnerable to chemical resistance for chemical solution that is used in a process for forming the contact pads 140 on the ceramic stacked structure 110, for example, a PR process, a plating process, an etching process, and so on.

However, since the multilayer ceramic substrate in accordance with an embodiment of the present invention is provided with surface reforming layers 111a and 115a which are positioned on the surfaces of the upper and lower parts of the ceramic stacked structure 110 and have no glass component vulnerable to chemical resistance, the surfaces of the ceramic stacked structure 110 fail to be damaged even after the PR process, the plating process, and the etching process. Therefore, it is possible to implement superior interfacial adhesion between the ceramic stacked structure 110 and the contact pads 140, and to maintain strength of the ceramic substrate.

In case where the interfacial adhesion between the ceramic stacked structure 110 and the contact pads 140 is superior, it is possible to not only achieve prevention of electrical leakage resistance and improvement of RF circuit signal transmission power, but also to implement integrated pad line width, resulting in securing design freedom for mounting a resistor, an inductor, and an MLCC.

The contact pads 140 are electrically connected to the vias 122, and may be disposed on the top surface and bottom surface of the ceramic stacked structure 110, respectively.

The contact pads 140 may be formed of single layer composed of at least one of conductive materials such as Cu, Ni, and Au, or a multiple layer sequentially stacked with Cu, Ni, and Au.

Herein, in case where the electrical component formed by using multilayer ceramic substrate is used to form a probe substrate, the contact pads 140 disposed on the top surface of the ceramic stacked structure 110 may come into electrical contact with the print circuit board which receives a feed-back of test signals. Further, other examples of the electrical component include a passive element or a semiconductor IC chip.

Furthermore, in case where a device formed by using the multilayer ceramic substrate, is used to form a probe substrate, the contact pads 140 disposed on the bottom surface of the ceramic stacked structure 110 may come into electrical contact with probe pins which comes into electrical contact with the semiconductor device of being a test object.

Herein, since the multilayer ceramic substrate in accordance with an embodiment of the present invention has surface reforming layers 111a and 115a obtained by removal of glass component formed on surfaces of the ceramic stacked structure 110, it is possible to prevent bonding strength between the ceramic stacked structure 110 and the contact pads 140 from being reduced, which results in improvement of bondability between the multilayer ceramic substrate and the probe pins. Thus, leakage resistance between the multilayer ceramic substrate and the probe pins can be reduced, which results in improvement of electric characteristics of the probe substrate.

Further, conductive adhesive patterns 131 may be further provided between the contact pads 140 and the ceramic stacked structure 110. The conductive adhesive patterns 131 can play a role of improving reliability of the contact pads 140 by enhancing adhesive strength between the contact pads 140 and the ceramic stacked structure 110. Herein, the conductive adhesive patterns 131 may be composed of a material, including at least one of Ti, Ni, and Cr. That is, the conductive adhesive patterns 131 may be formed in a single film, or double film or more. Further, the conductive adhesive patterns 131 may be made of a single component composed of any one selected from Ti, Ni, and Cr, or may be made of a mixed component obtained by co-depositing two or more ones selected from Ti, Ni, and Cr.

Furthermore, plating seed patterns 132 used as a seed layer of a plating process for formation of the contact pads 140 may be further provided between the conductive adhesive patterns 131 and the contact pads 140.

Therefore, the multilayer ceramic substrate in accordance with the embodiment of the present invention is provided with the surface reforming layers 111a and 115a formed by removal of glass component formed on the surfaces of the ceramic stacked structure 110, so that it is possible to enhance chemical resistance and durability of the multilayer ceramic substrate, which results in improvement of reliability and electric characteristics of electric components formed by using the multilayer ceramic substrate.

Also, it has been shown and illustrated in the embodiment of the present invention that the ceramic stacked structure 110 is formed by stacking five ceramic layers, which is provided for illustrative purpose. However, the present invention is not limited thereto.

Also, although it has been shown and illustrated in the embodiment of the present invention that each of the surface reforming layers 111a and 115a is formed on the surfaces of the lower and upper parts of the ceramic stacked structure 110, the number of the surface modification layers 111a and 115a having no glass component is not limited thereto.

Hereinafter, a detailed description will be given of a method for manufacturing a multilayer ceramic substrate in accordance with an embodiment of the present invention with reference to FIGS. 2 to 8.

FIGS. 2 to 8 are cross-sectional views sequentially illustrating processes of a method for manufacturing a multiple ceramic substrate in accordance with the embodiment of the present invention.

As shown in FIG. 2, in order to manufacture the multilayer ceramic substrate, the ceramic stacked structure 110 may be provided in which a plurality of ceramic layers 111, 112, 113, 114, and 115 are stacked and interconnected to one another through the vias 112.

The ceramic stacked structure 110 may be formed by allowing green sheets having the vias 122 to be stacked in multiple layers and firing the stacked green sheets. In the stacked green sheets, interlayer connection can be achieved through the vias 122 provided on each of layers. Further, the green sheets further include inner circuit patterns 123 connected to the vias 122.

Herein, the ceramic stacked structure 110, which corresponds to an LTCC substrate formed by being subjected to low-temperature firing at a temperature of 900° C. or lower, may be provided with ceramic layers 111, 112, 113, 114, and 115, each of which may contain a large amount of glass component, such as SiO2, CaCO3, ZnO, 8203, and so on.

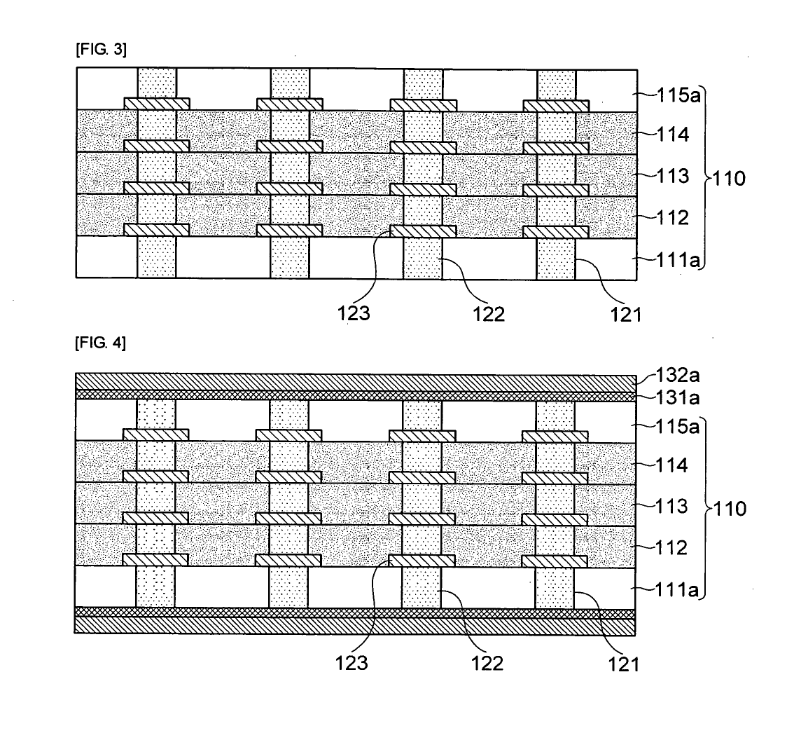

Thereafter, as shown in FIG. 3, among ceramic layers 111, 112, 113, 114, and 115 constituting the ceramic stacked structure 110, glass component contained in the ceramic layers 111 and 115 positioned on the surfaces of the upper and lower parts of the ceramic stacked structure 110 is removed, thereby forming surface reforming layers 111a and 115a.

Herein, in order to form the surface reforming layers 111a and 115a, a surface reforming treatment used to remove glass component from the ceramic layers 111 and 115 positioned on the surfaces of the upper and lower parts of the ceramic stacked structure 110 may be performed by a chemical treatment method, or a physical treatment method.

First, in case where the chemical treatment method is used, the glass component can be removed by using chemical solution capable of melting the glass component, for example, chemical solution including at least one of strong acids (e.g. HF, HCl, and so on) and strong bases (e.g. KOH, NaOH, and so on). At the time of the chemical treatment, the chemical solution is heat-treated at a temperature of 40° C. to 80° C. to thereby form a vortex.

The glass component of the surfaces of the ceramic stacked structure 110 is melted by the chemical solution to thereby form the surface reforming layers 111a and 115a, and then the resultant surface reforming layers 111a and 115a are subjected to washing and drying through alcohol, DI (Distilled water), or the like. Thereafter, the surfaces of the surface reforming layers 111a and 115a are subjected to a polishing treatment, so as to reinforce adhesive force between the ceramic stacked structure 110 and the contact pads 140 which are to be formed.

Alternatively, in case where the surface reforming layers 111a and 115a are formed through the physical treatment method, instead of the chemical treatment method, at least one of laser beams, a plasma source, and microwave is used so that the glass component can be melted above a melting point of the glass component, for removal of the glass component.

After being provided with the surface reforming layers 111a and 115a obtained by removing glass component through the physical treatment, the multilayer ceramic substrate can have enhanced chemical resistance and mechanical characteristics through polishing, washing, and drying treatments.

That is, in accordance with an embodiment of the present invention, the multilayer ceramic substrate is provided with surface reforming layers 111a and 115a, obtained by removing the glass component on the surfaces of the upper and lower parts of the ceramic stacked structure 110 through surface reforming treatment as described above. Therefore, it is possible to stably secure chemical resistance of the surfaces of the ceramic stacked structure 110 from chemical solution used in a process for forming the contact pads 140 which is to be described below, for example, a PR process, a plating process, an etching process, and so on, and accordingly, to improve interfacial adhesion between the ceramic stacked structure 110 and the contact pads 140.

Then, as shown in FIG. 4, conductive adhesive layers 131a and plating seed layers 132a are sequentially formed on both sides of the ceramic stacked structure 110 having the surface reforming layers 111a and 115a.

Examples of the conductive adhesive layers 131a may include at least any one of, or two or more of Ti, Ni, and Cr.

The plating seed layers 132a play a role of a seed for formation of the contact pads 140 which are to be described. As for material of the plating seed layers 132a, Cu may be exemplified.

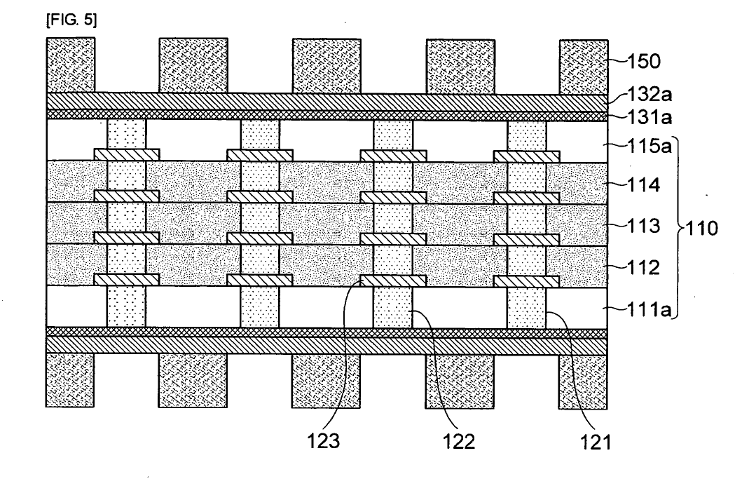

Thereafter, as shown in FIG. 5, resist patterns 150 are formed on the plating seed layers 132a. The resist patterns 150 may be formed to expose parts corresponding to the vias 121. The resist patterns 150 may be formed by either attaching a dry film, or forming a photoresist film on the plating seed layers 132a prior to performing an exposing process and a developing process.

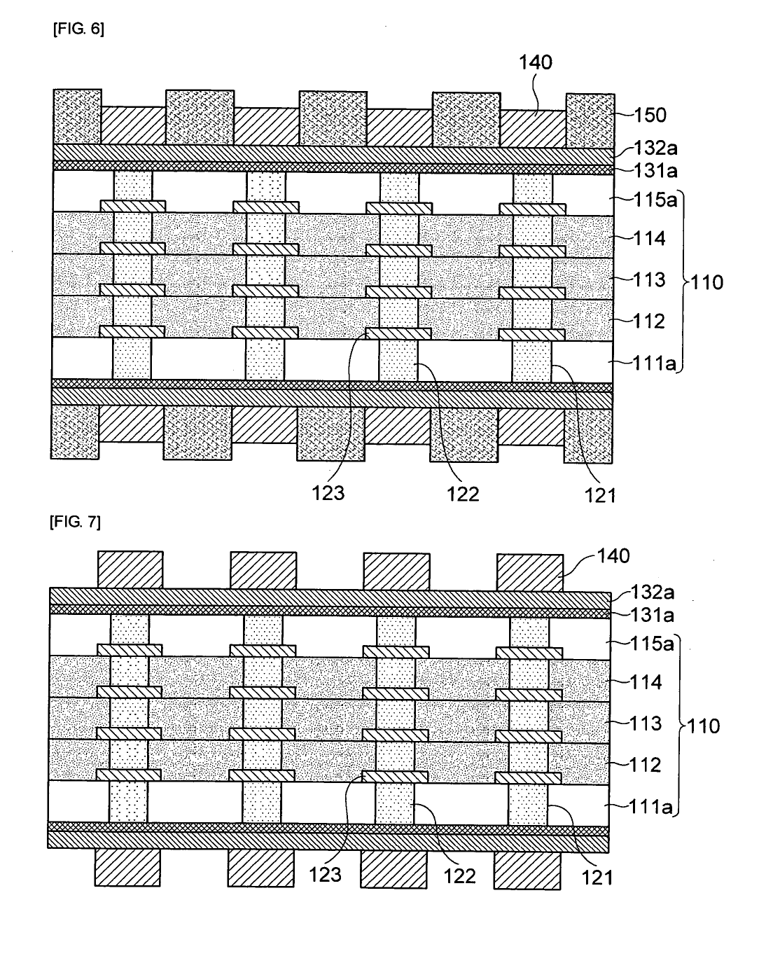

Thereafter, as shown in FIG. 6, a plating process is provided on the plating seed layers 132a exposed by the resist patterns 150 to thereby form the contact pads 140. Herein, the contact pads 140 may be formed of a single layer composed of any one of Cu, Ni, and Au, or a multiple layer formed by being sequentially plated with Cu, Ni, and Au.

Thereafter, as shown in FIG. 7, the resist patterns 150 are removed.

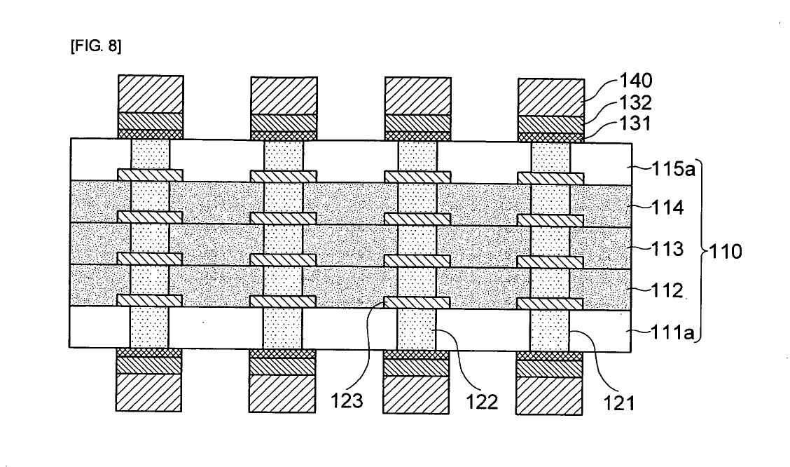

Herein, in accordance with an embodiment of the present invention, the surface reforming layers 111a and 115a having no glass component is provided in the ceramic stacked structure 110, so that it is possible to prevent the surfaces of the ceramic stacked structure 110 from being corroded due to developing solution (e.g. TMAH, and so on) used in a PR process for formation of the resist patterns 150, and plating solution (e.g. sulfuric acid, chlorides, and so on) used in a plating process of the contact pads 140. Thereafter, as shown in FIG. 8, parts of the conductive adhesive layers 131a and plating seed layers 132a exposed by removal of the resist patterns 150 are subjected to an etching process to thereby form each of the plating seed patterns 132 and the conductive adhesive patterns 131. Thus, the contact pads 140 electrically connected to the vias 121 can be formed.

Herein, the etching process may be a wet etching process. In this case, since the ceramic stacked structure 110 is provided with the surface reforming layers 111a and 115a, there is no need to concern about damage of the surfaces of the ceramic stacked structure 110 due to chemical solution of either strong acids like HF, or strong bases like KOH used in the wet etching process.

As described above, in the method for forming the multilayer ceramic substrate in accordance with an embodiment of the present invention, the surface reforming layers 111a and 115a are formed by removing glass component of the ceramic layers positioned on the surfaces of the upper and lower parts of the ceramic stacked structure 110, so that it is possible to secure chemical resistance of the surfaces of the ceramic stacked structure 110 from chemical solution used in a PR process, a plating process, and an etching process which are required for formation of the contact pads 140, which results in improvement of interfacial adhesion between the ceramic stacked structure 110 and the contact pads 140.

That is, according to the embodiment of the present invention, the sticking strength of the contact pads can be increased two times more than that of the conventional contact pads, i.e. to 35 N/mm² from 16 N/mm². Thus, electrical components formed by using multilayer ceramic substrate of the present invention can prevent electrical leakage resistance and improve RF circuit signal transmission power. Further, it is possible to implement integrated pad line width, which results in securing design freedom for mount of a resistor, an inductor, and an MLCC.

Further, it is possible to prevent corrosion of the surfaces of the ceramic stacked structure 110, and deposit of the glass component, and accordingly, to increase the strength of the multiple ceramic substrate to more than 350 Mpa from 200 MPa, which results in use for electrical component having high strength and durability.

Further, in accordance with an embodiment of the present invention, dust is not generated through prevention of deposit of glass component, so that it is possible to reduce defective rate caused by the dust, and thus to improve workability and mass production.

As described above, according to a multilayer ceramic substrate and a manufacturing method thereof, glass component of the surfaces of the upper and lower parts of the ceramic stacked structure is removed to thereby form the surface reforming layers, so that it is possible to secure chemical resistance of the ceramic stacked surface from chemical solution used in a PR process, a plating process, an etching process that are required for formation of subsequent contact pads.

Therefore, the present invention can improve interfacial adhesion between the ceramic stacked structure and the contact pads, and enhance sticking strength of the contact pads.

Thus, electric components formed by using multilayer ceramic substrate of the present invention can prevent electrical leakage resistance and improve RF circuit signal transmission power.

Also, the present invention can have an advantage in that it is possible to secure chemical resistance of surfaces of the ceramic stacked structure, thereby implementing integrated pad line width, which results in securing design freedom for mounting a resistor, an inductor, and an MLCC.

Also, the present invention can improve strength of the multilayer ceramic substrate by preventing corrosion of the ceramic stacked structure, and deposit of the glass component.

Also, the present invention can allow dust not to be generated through prevention of deposit of glass component, so that it is possible to reduce defective rate caused by the dust, and thus to improve workability and mass production.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. A multilayer ceramic substrate comprising:
a ceramic stacked structure in which multiple ceramic layers are stacked and interconnected to one another through vias provided in respective ceramic layers, the ceramic stacked structure having surface reforming layers formed by removal of glass component on the surfaces of upper and lower parts of the ceramic layers; and
contact pads formed on a top surface and a bottom surface of the ceramic stacked structure so as to be electrically connected to the vias.

2. The multilayer ceramic substrate of claim 1, wherein each ceramic layer except for the surface reforming layers of the ceramic stacked structure contains glass component.

3. The multilayer ceramic substrate of claim 1, further comprising conductive adhesive patterns interposed between the contact pads and the ceramic stacked structure.

4. The multilayer ceramic substrate of claim 3, wherein the conductive adhesive patterns include at least one of Ni, Ti, and Cr.

5. The multilayer ceramic substrate of claim 3, further comprising plating seed patterns interposed between the conductive adhesive patterns and the contact pads.

6. The multilayer ceramic substrate of claim 1, wherein the contact pads include at least one of Cu, Ni, and Au.

7. A method for manufacturing a multilayer ceramic substrate comprising:
providing a ceramic stacked structure in which multiple ceramic layers containing glass component are stacked, and are interconnected through vias provided in respective ceramic layers;
removing glass component of ceramic layers positioned on surfaces of upper and lower parts of the ceramic stacked structure, thereby forming surface reforming layers; and
forming contact pads on a top surface and a bottom surface of the ceramic stacked structure having the surface reforming layers formed thereon, the contact pads being electrically connected to the vias.

8. The method of claim 7, wherein, in the removing, the glass component is removed from the ceramic layers positioned on the surfaces of the upper and lower parts of the ceramic stacked structure through a chemical treatment method.

9. The method of claim 8, wherein the chemical treatment method is based on the fact that the glass component is removed by using chemical solution including at least any one of HF, and HCl as strong acids, and KOH, and NaOH as strong bases.

10. The method of claim 7, wherein, in the removing, the glass component is removed from the ceramic layers positioned on the surfaces of the upper and lower parts of the ceramic stacked structure through a physical treatment method.

11. The method of claim 10, wherein the physical treatment method is based on the fact that the glass component is removed by using at least any one of laser beams, a plasma source, and microwave.

12. The method of claim 7, further comprising performing a polishing treatment for surfaces of the surface reforming layers, after the removing.

13. The method of claim 7, wherein the forming comprises:
sequentially forming conductive adhesive layers and plating seed layers on the ceramic stacked structure having the surface reforming layers formed thereon;
forming resist patterns on the plating seed layer;
performing a plating process on the plating seed layers exposed by the resist patterns, thereby forming the contact pads;
removing the resist patterns; and
etching parts of the conductive adhesive layers and the plating seed layers exposed by removal of the resist patterns, thereby forming plating seed patterns and conductive adhesive patterns, respectively.
